(19) United States
(12) Patent Application Publication
(10) Pub. No.: US 2022/0140459 A1
(43) Pub. Date: May 5, 2022

(54) SUPPORT DEVICE FOR PHASE SHIFTER FOR BASE STATION ANTENNA

(71) Applicant: CommScope Technologies LLC, Hickory, NC (US)

(72) Inventors: Yongfeng Liu, Suzhou (CN); HanXing Xu, Suzhou (CN); ZhaoHui Liu, Suzhou (CN)

(21) Appl. No.: 17/477,896

(22) Filed: Sep. 17, 2021

(30) Foreign Application Priority Data
Nov. 5, 2020 (CN) 202011221233.6

(51) Int. Cl. H01P 1/18; H05K 1/02

(52) U.S. Cl. CPC H01P 1/18; H05K 2201/10098; H05K 1/0243

(57) ABSTRACT

The present disclosure relates to a support device for a phase shifter for a base station antenna. The support device includes a support plate suitable for fixation of a main printed circuit board of the phase shifter. The support plate includes a plate-shaped body and at least one support leg located at a lower portion of the body. At least one said support leg extends along a direction perpendicular to the body and is located on one side of the body, so that the support plate can be arranged in the base station antenna in a first orientation by at least one said support leg, or arranged in the base station antenna in a second orientation by the body itself according to layout requirements. The present disclosure also relates to an assembly for a phase shifter for a base station antenna and a method for soldering a coaxial cable to a phase shifter for a base station antenna.

### RELATED APPLICATION

The present application claims priority from and the benefit of Chinese Patent Application No. 202011221233.6, filed Nov. 5, 2020, the disclosure of which is hereby incorporated herein in its entirety.

### FIELD OF THE INVENTION

The present disclosure generally relates to a communication system. More particularly, the present disclosure relates to a support device for a phase shifter for a base station antenna, and a method for soldering a coaxial cable to a phase shifter for a base station antenna.

### BACKGROUND OF THE INVENTION

A cellular communication system is used to provide wireless communication to stationary and mobile users. The cellular communication system may include a plurality of base stations, and each base station provides wireless cellular service for a designated coverage area (generally referred to as a “cell”). Each base station may include one or more base station antennas, and the base station antenna is used to transmit radio frequency (“RF”) signals to a user located in a cell served by the base station and receive RF signals from the user. The base station antenna is a directional device that can converge RF energy transmitted in certain directions or received from certain directions. A “gain” of a base station antenna in a given direction is a measure of the ability of the antenna to converge RF energy in that direction. A “radiation pattern” of a base station antenna (also referred to as an “antenna beam”) is the compilation of the gain of the antenna in all different directions. Each antenna beam can be designed to serve a predetermined coverage area, for example, a cell or a part of a cell (referred to as a “sector”). The base station antenna usually include linear arrays of radiating elements (for example, patches, dipoles, or crossed dipole radiating elements), and each linear array generates its own antenna beam.

Most prior art base station antennas are configured to be capable of electronically changing the elevation or “tilt” angle of the antenna beam generated by the antenna, and this can be realized by a phase shifter. A widely used phase shifter is a brush-type phase shifter, which includes a main printed circuit board and a sliding piece that can rotate above the main printed circuit board. The brush type phase shifter usually divides an input RF signal received at the main printed circuit board into a plurality of sub-components, and then couples at least some of the sub-components to the sliding piece. The sub-components of the RF signal can be coupled from the sliding piece back to the main printed circuit board along a plurality of arc-shaped tracks (where each arc has a different diameter). Each end portion of each arc-shaped track may be connected to each sub-group of radiating elements including at least one radiating element. By physically (mechanically) rotating the sliding piece above the main printed circuit board, it is possible to change the positions where the sub-components of the RF signal are coupled back to the main printed circuit board, thereby changing the lengths of transmission paths from the phase shifter to each sub-group of radiating elements. The path length changes result in changes in the phases of the sub-components of the RF signal, thereby changing the elevation or “tilt” angle of the antenna beam.

In prior art base station antennas, the main printed circuit board of the phase shifter is usually arranged in a tiled manner on a reflector of the base station antenna. However, with the continuous improvement of the base station antenna, the number of parts in the base station antenna has increased significantly. The arrangement in a tiled manner significantly increases the difficulty of the layout of the parts in the base station antenna, and thus increases the risk of mechanical or electrical interference between the parts.

### SUMMARY OF THE INVENTION

One of the objectives of the present disclosure is to overcome at least one defect in the prior art.

In a first aspect of the present disclosure, a support device for a phase shifter for a base station antenna is provided. The support device includes a support plate suitable for fixation of a main printed circuit board of the phase shifter, the support plate includes a plate-shaped body and at least one support leg located at a lower portion of the body, at least one said support leg extends along a direction perpendicular to the body and is located on one side of the body, so that the support plate can be arranged in the base station antenna in a first orientation by at least one said support leg, or arranged in the base station antenna in a second orientation by the body itself according to layout requirements.

According to an embodiment of the present disclosure, the body includes a front surface and a rear surface, and at least one surface of the front surface and the rear surface is suitable for fixation of the main printed circuit board of the phase shifter.

According to an embodiment of the present disclosure, at least one said surface of the front surface and the rear surface includes one or more receiving portions suitable for accommodation of outer conductors of one or more coaxial cables.

According to an embodiment of the present disclosure, the one or more accommodating portions are positioned to be near an end portion of a corresponding transmission line track of the main printed circuit board when the main printed circuit board of the phase shifter is positioned on at least one said surface, so that when the outer conductor of the coaxial cable is accommodated in the accommodating portion, an inner conductor of the coaxial cable can contact the end portion of the corresponding transmission line track to transmit a signal.

According to an embodiment of the present disclosure, at least one said surface of the front surface and the rear surface includes one or more support portions suitable for support of the main printed circuit board of the phase shifter.

According to an embodiment of the present disclosure, the support portion is adjacent to a corresponding accommodating portion.

According to an embodiment of the present disclosure, at least a part of a back surface of the main printed circuit board of the phase shifter is soldered on the support portion.

According to an embodiment of the present disclosure, the support portion includes a recessed portion for placing solder.

According to an embodiment of the present disclosure, the support portion includes a channel for exhaust during soldering, and the channel is in fluid connection with a corresponding accommodating portion.

According to an embodiment of the present disclosure, at least one said surface of the front surface and the rear surface includes a plurality of the support portions, and an opening penetrating the support plate is provided between adjacent support portions for rapid heat dissipation during soldering.

According to an embodiment of the present disclosure, the support portion and the accommodating portion are spaced apart from each other by a gap penetrating the body of the support plate.

According to an embodiment of the present disclosure, the main printed circuit board of the phase shifter includes a soldering portion suitable for soldering of the outer conductor of the coaxial cable, and when the main printed circuit board of the phase shifter is placed on at least one said surface of the support plate, the soldering portion is located above the gap without contacting the support plate.

According to an embodiment of the present disclosure, the soldering portion of the main printed circuit board of the phase shifter includes an opening for accommodating the outer conductor of the coaxial cable.

According to an embodiment of the present disclosure, at least one said surface includes one or more support protrusions for supporting the corresponding transmission line track of the main printed circuit board of the phase shifter, and the support protrusion has a contour that is the same as that of the corresponding transmission line track.

According to an embodiment of the present disclosure, at least one said surface includes a plurality of positioning protrusions for positioning the main printed circuit board of the phase shifter.

According to an embodiment of the present disclosure, each of the positioning protrusions includes a positioning hole, and a fastening element is positioned in the positioning hole to position the main printed circuit board on the support plate.

According to an embodiment of the present disclosure, the fastening element includes a pin or a screw.

According to an embodiment of the present disclosure, a plurality of fixing lugs are provided at different positions of the body of the support plate for fixing the body of the support plate when the support plate is arranged in the second orientation by the body.

According to an embodiment of the present disclosure, a top portion of the support plate has a contour that the same as that of a top portion of the main printed circuit board of the phase shifter.

According to an embodiment of the present disclosure, the body of the support plate includes a plurality of cavities penetrating the body.

According to an embodiment of the present disclosure, the support device further includes a sliding piece support member for a sliding piece of the phase shifter, one end of the sliding piece support member is rotatably fixed on the support plate, and the sliding piece support member can drive the sliding piece to rotate relative to the main printed circuit board when rotating, so as to adjust a phase of the phase shifter.

According to an embodiment of the present disclosure, the one end of the sliding piece support member is fixed on the support plate by a second fastening element, and the second fastening element is configured to be capable of adjusting its fastening force to adjust contact pressure between the sliding piece and the main printed circuit board.

In a second aspect of the present disclosure, an assembly for a phase shifter for a base station antenna is provided. The assembly includes the support device for a phase shifter for a base station antenna according to the present disclosure and at least one printed circuit board mounted on the support plate of the support device.

According to an embodiment of the present disclosure, the assembly further includes one or more coaxial cables that are soldered on corresponding portions of the support plate and the printed circuit board.

In a third aspect of the present disclosure, a method for soldering a coaxial cable to a phase shifter for a base station antenna is provided. The method includes: 1) providing a support plate for the phase shifter, at least one surface of the support plate being suitable for fixation of a main printed circuit board of the phase shifter and including one or more accommodating portions suitable for accommodation of outer conductors of one or more coaxial cables; 2) placing the main printed circuit board of the phase shifter on the support plate so that an end portion of a corresponding transmission line track of the main printed circuit board is near the accommodating portion of the support plate; 3) placing the outer conductors of the one or more coaxial cables in the corresponding accommodating portions of the support plate respectively, and bringing inner conductors of the one or more coaxial cables into contact with the end portions of the corresponding transmission line tracks of the main printed circuit board; and 4) using a soldering device to solder the support plate, the main printed circuit board, and the coaxial cable, so as to solder the coaxial cable on the support plate and/or the main printed circuit board.

According to an embodiment of the present disclosure, the soldering device is an induction soldering device, and wherein, the method comprises a step of applying solder to corresponding soldering parts of the support plate, the main printed circuit board and the coaxial cable before step 4).

According to an embodiment of the present disclosure, the soldering device is a wave soldering device, and wherein, a liquid solder is applied directly to corresponding soldering parts of the support plate, the main printed circuit board and the coaxial cable in the step 4).

According to an embodiment of the present disclosure, the support plate includes a support portion for supporting the main printed circuit board, the support portion is adjacent to the accommodating portion, and at least a part of a back surface of the main printed circuit board is soldered on the support portion.

According to an embodiment of the present disclosure, at least a part of the back surface of the main printed circuit board is soldered on the support portion by an induction soldering device before step 3).

According to an embodiment of the present disclosure, at least a part of the back surface of the main printed circuit board is soldered on the support portion by a wave soldering device in step 4).

According to an embodiment of the present disclosure, the support plate includes a support portion for supporting the main printed circuit board, the support portion and the accommodating portion are spaced apart from each other by a gap penetrating the body of the support plate, wherein, the main printed circuit board includes a soldering portion suitable for soldering of the outer conductor of the coaxial cable, and in step 2), the soldering portion is arranged above the gap without contacting the support plate.

According to an embodiment of the present disclosure, the soldering portion of the main printed circuit board includes an opening, and in step 3), the outer conductor of the coaxial cable is placed in the opening.

It should be noted that various aspects of the present disclosure described for one embodiment may be included in other different embodiments, although specific description is not made for the other different embodiments. In other words, all the embodiments and/or features of any embodiment may be combined in any manner and/or combination, as long as they are not contradictory to each other.

### BRIEF DESCRIPTION OF THE DRAWINGS

A plurality of aspects of the present disclosure will be better understood after reading the following specific embodiments with reference to the attached drawings. In the attached drawings:

FIG. 1 is an exploded perspective view of a support device for a phase shifter for a base station antenna, a phase shifter to be mounted on the support device, and an input/output coaxial cable according to a first embodiment of the present disclosure.

FIG. 2 is a perspective view of a support plate of the support device according to the first embodiment of the present disclosure.

FIG. 3 is a front view of the support device according to the first embodiment of the present disclosure on which a phase shifter and an input/output coaxial cable are mounted.

FIG. 4 is a side view of the support device according to the first embodiment of the present disclosure on which a phase shifter and an input/output coaxial cable are mounted.

FIG. 5 shows a front side of a main printed circuit board of a phase shifter suitable for being mounted on the support device according to the first embodiment of the present disclosure.

FIG. 6 shows a back side of the main printed circuit board of the phase shifter suitable for being mounted on the support device according to the first embodiment of the present disclosure.

FIG. 7 is a perspective view of a support plate of a support device for a phase shifter for a base station antenna according to a second embodiment of the present disclosure.

FIG. 8 shows a front side of a main printed circuit board of a phase shifter suitable for being mounted on the support device according to the second embodiment of the present disclosure.

FIG. 9 shows a back side of the main printed circuit board of the phase shifter suitable for being mounted on the support device according to the second embodiment of the present disclosure.

FIG. 10 is a perspective view of the support device according to the second embodiment of the present disclosure on which a phase shifter and an input/output coaxial cable are mounted.

It should be understood that in all the attached drawings, the same reference numerals and signs denote the same elements. In the attached drawings, for clarity, the size of certain features is not drawn based on the scale as it may change.

### DESCRIPTION OF THE EMBODIMENTS

The present disclosure will be described below with reference to the attached drawings, and the attached drawings illustrate several embodiments of the present disclosure. However, it should be understood that the present disclosure may be presented in many different ways and is not limited to the embodiments described below; in fact, the embodiments described below are intended to make the disclosure of the present disclosure more complete and to fully explain the protection scope of the present disclosure to those skilled in the art. It should also be understood that the embodiments disclosed in the present disclosure may be combined in various ways so as to provide more additional embodiments.

It should be understood that the words in the specification are only used to describe specific embodiments and are not intended to limit the present disclosure. Unless otherwise defined, all terms (including technical terms and scientific terms) used in the specification have the meanings commonly understood by those skilled in the art. For brevity and/or clarity, well-known functions or structures may not be further described in detail.

The singular forms “a”, “an”, “the” and “this” used in the specification all include plural forms unless clearly indicated. The words “include”, “contain” and “have” used in the specification indicate the presence of the claimed features, but do not exclude the presence of one or more other features. The word “and/or” used in the specification includes any or all combinations of one or more of the related listed items.

In the specification, when it is described that an element is “on” another element, “attached” to another element, “connected” to another element, “coupled” to another element, or “in contact with” another element, etc., the element may be directly on another element, attached to another element, connected to another element, coupled to another element, or in contact with another element, or an intermediate element may be present.

In the specification, the terms “first”, “second”, “third”, etc. are only used for convenience of description and are not intended for limitation. Any technical features represented by “first”, “second”, “third”, etc. are interchangeable.

In the specification, terms expressing spatial relations such as “upper”, “lower”, “front”, “rear”, “top”, and “bottom” may describe the relation between one feature and another feature in the attached drawings. It should be understood that, in addition to the orientations shown in the attached drawings, the words expressing spatial relations further include different orientations of a device in use or operation. For example, when a device in the attached drawings rotates reversely, the features originally described as being “below” other features now can be described as being “above” the other features. The device may also be oriented in other directions (rotated by 90 degrees or in other orientations), and in this case, a relative spatial relation will be explained accordingly.

Referring to FIG. 1, it shows a support device 10 for a phase shifter for a base station antenna according to the first embodiment of the present disclosure. The support device 10 may include a support plate 101 having a plate-shaped body. The body of the support plate 101 may have a front surface 102 and a rear surface 103 opposite to the front surface 102, and at least one of the front surface 102 and the rear surface 103 is suitable for fixation of a main printed circuit board 104 of the phase shifter. In the embodiment shown in FIG. 1, the front surface 102 and the rear surface 103 are respectively suitable for fixation of the main printed circuit boards 104 of two different phase shifters, so that the support plate 101 can be sandwiched between the main printed circuit boards 104 of two different phase shifters. At least one support leg 105 may be provided at a lower portion of the body of the support plate 101, and the support leg extends in a direction perpendicular to the body of the support plate 101 and is located on one side of the body, so that the support plate 101 can be arranged in the base station antenna in different orientations according to layout requirements. For example, the support plate 101 can be arranged in the base station antenna in a first orientation (for example, a vertical direction) by at least one said support leg 105, or arranged in the base station antenna in a second orientation (for example, a horizontal direction) by the body itself of the support plate 101. This makes it possible to flexibly arrange the phase shifter in the base station antenna, thereby saving layout space in the base station antenna and reducing the risk of mutual interference of various parts in the base station antenna.

The support device 10 may further include a sliding piece support member 107 for a sliding piece 106 (also referred to as a “brush type printed circuit board”) of the phase shifter. One end 108 of the sliding piece support member 107 may be rotatably fixed on the support plate 101 and the other end 109 may be fixedly connected to a corresponding end of the sliding piece 106, so that the sliding piece support member can drive the sliding piece 106 to rotate relative to the main printed circuit board 104 when rotating, so as to adjust the phase of the phase shifter. When two different phase shifters are fixed on the front surface 102 and the rear surface 103 of the support plate 101, the sliding piece support member 107 can drive two sliding pieces 106 of the two different phase shifters at the same time to rotate relative to the respective main printed circuit board 104 when rotating, so as to adjust the phases of the two different phase shifters at the same time. The end 108 of the sliding piece support member 107 may be fixed on the support plate 101 by a fastening element (for example, a pin 110 and a pin-fitting element 110′ shown in FIG. 1).

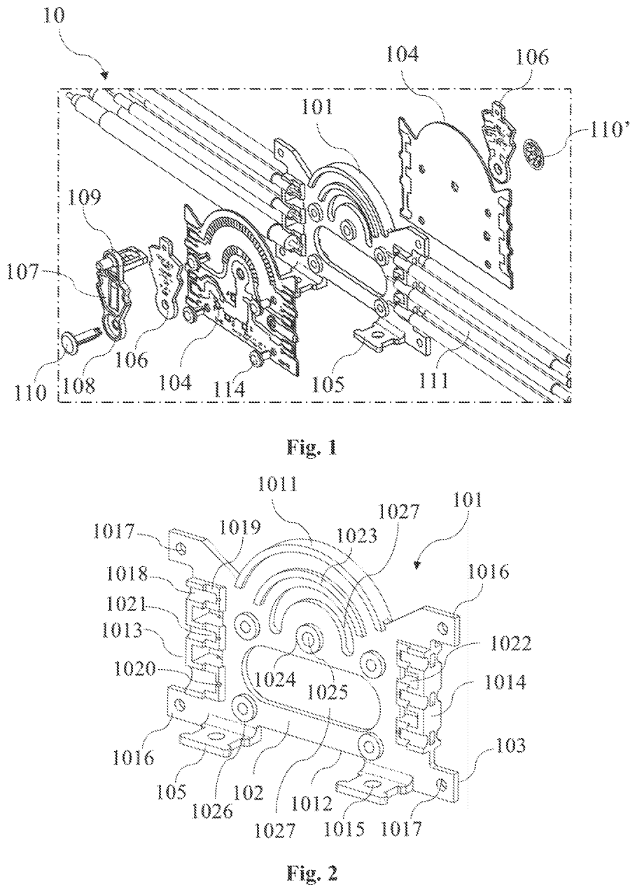

Referring to FIG. 2, it shows a specific structure of the support plate 101 of the support device 10 according to the first embodiment of the present disclosure. The body of the support plate 101 may include a top portion 1011, a bottom portion 1012, a left side portion 1013, and a right side portion 1014. The support leg 105 may be provided at the bottom portion 1012 of the support plate 101. In the embodiment shown in FIG. 2, two support legs 105 are provided, and they extend forward from the front surface 102 of the support plate 101 in a direction perpendicular to the body of the support plate 101. Each support leg 105 is provided with a positioning hole 1015 for fixing the support leg 105 when the support plate 101 is arranged in the first orientation by the support leg 105. Correspondingly, four fixing lugs 1016 are provided at four positions, i.e., the upper, lower, left, and right positions of the body of the support plate 101, and each fixing lug 1016 is provided with a positioning hole 1017 for fixing the body of the support plate 101 when the support plate 101 is arranged in the second orientation by the body of the support plate 101. The contour of the top portion 1011 of the support plate 101 may be the same as the contour of the top portion of the main printed circuit board 104 of the phase shifter. In the embodiment shown in FIG. 2, the top portion 1011 of the support plate 101 has an arc-shaped contour.

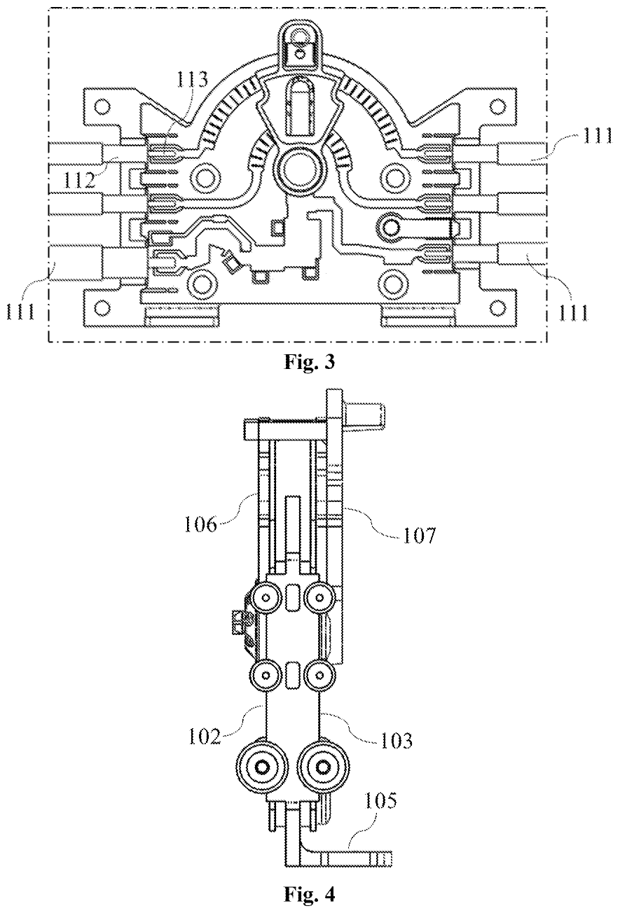

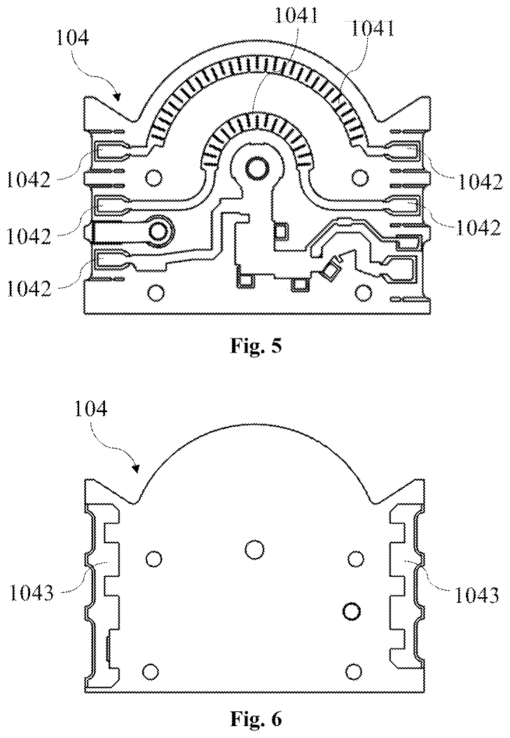

One or more accommodating portions 1018 for accommodating an outer conductor 112 of an input and/or output coaxial cable 111 are provided on the front surface 102 of the body of the support plate 101 near the left side portion 1013 and/or the right side portion 1014. The outer conductor 112 of the coaxial cable 111 may be soldered on a corresponding accommodating portion 1018 (see FIG. 3) for it to be grounded. The accommodating portion 1018 may include a groove for accommodating the outer conductor 112 of the coaxial cable 111 to facilitate positioning and soldering of the outer conductor 112. As shown in FIG. 3, the number of accommodating portions 1018 is configured to be the same as the number of input and/or output end portions 1042 (see FIG. 5) of transmission line tracks 1041 on the main printed circuit board 104 of the phase shifter, and each accommodating portion 1018 is positioned to be adjacent to the corresponding input and/or output end portion 1042 of the main printed circuit board 104 when the main printed circuit board 104 is placed on the front surface 102, so that when the outer conductor 112 of the coaxial cable 111 is accommodated in the groove of the accommodating portion 1018, an inner conductor 113 of the coaxial cable 111 can be conveniently positioned on the corresponding input and/or output end portion 1042 and contact the corresponding input and/or output end portion 1042 to input signals to the main printed circuit board 104 or output signals from the main printed circuit board 104.

In the embodiment shown in FIG. 2, a support portion 1019 for supporting the main printed circuit board 104 of the phase shifter is provided on an inner side of the accommodating portion 1018. The main printed circuit board 104 may be placed on the support portion 1019 and a corresponding part 1043 (see FIG. 6) of the back surface of the main printed circuit board 104 may be soldered on the support portion 1019. In order to facilitate the soldering of the main printed circuit board 104, a recessed portion 1020 may be provided on the support portion 1019 for placing solder (such as solder paste). In addition, in order to facilitate smooth exhaust during soldering, the support portion 1019 may further include a channel 1021 for exhaust. The channel 1021 may be in fluid connection with the groove of the accommodating portion 1018 to discharge gas generated during soldering. An opening 1022 penetrating the support plate may be provided between the support portions 1019, which helps to quickly dissipate heat during soldering.

The front surface 102 of the body of the support plate 101 may further include one or more support protrusions 1023 for supporting one or more transmission line tracks 1041 of the main printed circuit board 104 of the phase shifter. The number and/or contour of the support protrusions 1023 may be configured to be the same as the number and/or contour of the transmission line tracks 1041 on the main printed circuit board 104 of the phase shifter. The support protrusion 1023 is positioned to exactly correspond to the transmission line track 1041 on the main printed circuit board 104 when the main printed circuit board 104 is placed on the front surface 102 of the support plate 101, thereby supporting the transmission line track 1041. The support protrusion 1023 can effectively maintain the contact pressure between the main printed circuit board 104 and the sliding piece 106 of the phase shifter through its supporting effect, thereby ensuring stable electrical performance (for example, PIM performance, etc.) between the main printed circuit board 104 and the sliding piece 106. In the embodiment shown in FIG. 2, the support protrusion 1023 has a circular arc contour that is the same as that of the transmission line track 1041 on the main printed circuit board 104.

A positioning protrusion 1024 for positioning the sliding piece 106 of the phase shifter and the sliding piece support member 107 may be provided on the front surface 102 of the body of the support plate 101. A hole 1025 is provided on the positioning protrusion 1024, and a fastening element such as the pin 110 can extend through the hole 1025 to position the sliding piece support member 107 and the sliding piece 106 on the support plate 101 in a rotatable manner. The fastening force of the fastening element can be adjusted to adjust the contact pressure between the sliding piece 106 and the main printed circuit board 104, thereby adjusting the corresponding electrical performance of the phase shifter. In addition, a plurality of positioning protrusions 1026 for positioning the main printed circuit board 104 of the phase shifter may also be provided on the front surface 102 of the body of the support plate 101. Each positioning protrusion 1026 may be provided with a hole, and the fastening element 114 (as shown in FIG. 1, it may be a pin, a screw, and a fastening element in other appropriate forms) may be positioned in the hole of the positioning protrusion 1026 to position the main printed circuit board 104 on the support plate 101.

In the case where the support plate 101 is configured such that the front surface 102 and the rear surface 103 thereof are used to fix the main printed circuit boards 104 of two different phase shifters, the rear surface 103 may have the same configuration as the front surface 102, so that the body of the support plate 101 has a substantially mirror image structure. However, the support leg 105 is provided on only one surface of the front surface 102 and the rear surface 103 so as not to interfere with the arrangement of the support plate 101 when the support plate 101 is arranged, for example, lying flat, in the base station antenna by its body.

In addition, as shown in FIG. 2, a plurality of cavities 1027 penetrating the body are provided on the body of the support plate 101. The cavities 1027 can contribute to the rapid heat dissipation of the support plate 101 during soldering on one hand, and can improve the electrical performance of the phase shifter by changing the contact area between the main printed circuit board 104 and the support plate 101 on the other hand. In addition, the existence of the cavities 1027 can also save materials and reduce the weight of the support plate 101.

In an embodiment according to the present disclosure, the support plate 101 may be made of metal. The fastening elements 110 and 114 may be made of plastic.

When the support device 10 of the first embodiment of the present disclosure is used, the input and/or output coaxial cable 111 can be simultaneously soldered on the support plate 101 and the main printed circuit board 104 of the phase shifter by a single soldering operation. Specifically, the following steps are used to perform soldering: 1) placing the main printed circuit board 104 of the phase shifter on the support plate 101; 2) placing the outer conductor 112 of each coaxial cable 111 in the groove of the accommodating portion 1018 of the support plate 101 and bringing the inner conductor 113 of each coaxial cable 111 into contact with the corresponding input and/or output end portion 1042 of the transmission line track 1041 of the main printed circuit board 104; and 3) using a soldering device to solder the support plate 101, the main printed circuit board 104, and the coaxial cable 111, so as to solder the coaxial cable 111 on the support plate 101 and the main printed circuit board 104 at the same time. The soldering device may be an induction soldering device or a wave soldering device. When an induction soldering device is used, it is necessary to apply solder (such as tin paste) to corresponding parts of the support plate 101, the main printed circuit board 104 and the coaxial cable 111 before soldering, and then use the heating coil of the induction soldering device to heat and melt the solder to perform soldering. When a wave soldering device is used, there is no need to apply solder to corresponding parts of the support plate 101, the main printed circuit board 104 and the coaxial cable 111, and the wave soldering device directly sprays liquid solder on corresponding soldering parts to perform soldering. By using the support device 10 according to the first embodiment of the present disclosure, it is possible to solder each coaxial cable 111 on the support plate 101 and the main printed circuit board 104 at the same time through a single soldering operation. This not only significantly reduces the number of steps and the time for soldering, but also ensures that all coaxial cables 111 have consistent soldering quality because only a single soldering operation is required. As a result, consistent electrical performance is ensured.

In the support device 10 according to the first embodiment of the present disclosure, the back surface of the main printed circuit board 104 of the phase shifter also needs to be soldered on the support portion 1019 of the support plate 101, which is usually performed by an induction soldering device. Therefore, solder can be applied to the corresponding part 1043 of the back surface of the main printed circuit board 104 and/or the recessed portion 1020 of the support portion 1019 before step 1), and the back surface of the main printed circuit board 104 may be soldered on the support portion 1019 of the support plate 101 before step 2), or the back surface of the main printed circuit board 104 may be soldered on the support portion 1019 of the support plate 101 at the same time as the coaxial cable 111 is soldered in step 3).

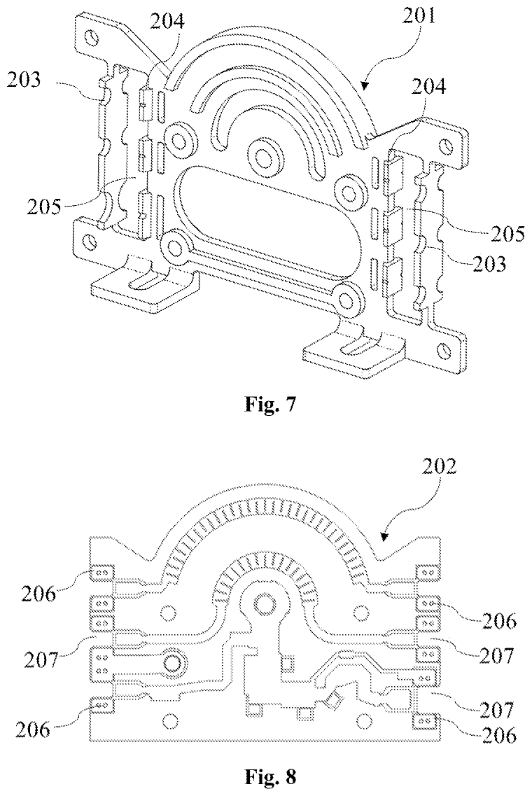

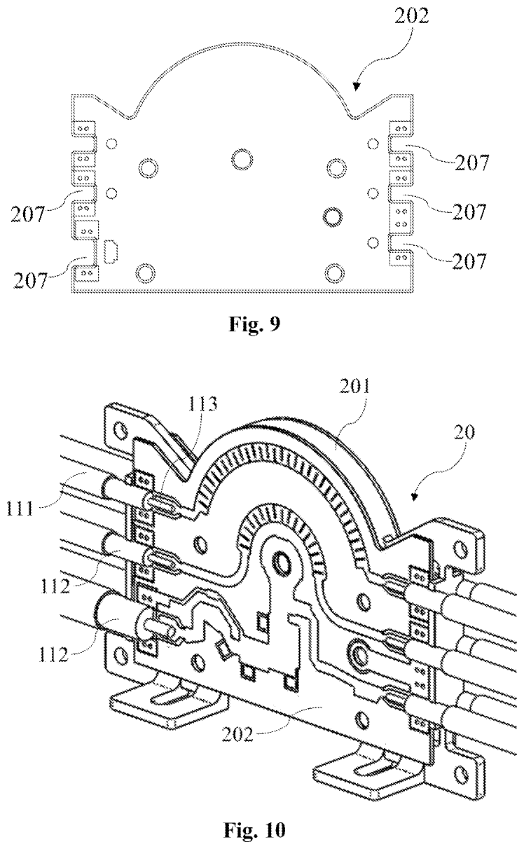

FIG. 7 to FIG. 10 show a support device 20 and a main printed circuit board 202 of a phase shifter used in cooperation with a support plate 201 of the support device 20 according to a second embodiment of the present disclosure. The support plate 201 of the support device 20 differs from the support plate 101 of the support device 10 as follows: an accommodating portion 203 for accommodating the outer conductor 112 of the coaxial cable 111 and a support portion 204 for supporting the main printed circuit board 202 are spaced apart from each other by a gap 205 penetrating the body of the support plate 201 (as shown in FIG. 7). Unlike the main printed circuit board 104, the back portion of the main printed circuit board 202 does not need to be soldered on the support plate 201. Correspondingly, the left side portion and the right side portion of the main printed circuit board 202 are provided with a soldering portion 206 suitable for soldering of the outer conductor 112 of the coaxial cable 111, and the soldering portion 206 is provided with an opening 207 for accommodating the outer conductor 112 of the coaxial cable 111 to facilitate soldering (as shown in FIG. 8 and FIG. 9). When the main printed circuit board 202 is placed on the support plate 201, the soldering portion 206 is located above the gap 205 between the accommodating portion 203 and the support portion 204 without contacting the support plate 201. When soldering is performed, the outer conductor 112 of the coaxial cable 111 is located in the opening of the soldering portion 206 and is soldered together with the soldering portion 206.

When the support device 20 of the second embodiment of the present disclosure is used, the following steps are used to perform soldering: 1) placing the main printed circuit board 202 on the support plate 201 so that the soldering portion 206 of the main printed circuit board 202 is located above the gap 205 of the support plate 201; 2) placing the outer conductor 112 of each coaxial cable 111 in the groove of the accommodating portion 203 of the support plate 201 and in the opening 207 of the main printed circuit board 202, and bringing the inner conductor 113 of each coaxial cable 111 into contact with the corresponding input and/or output end portion 2022 of the transmission line track 2021 of the main printed circuit board 202; and 3) using a soldering device to solder the support plate 201, the main printed circuit board 202 and the coaxial cable 111, so as to solder the coaxial cable 111 on the support plate 201 and the main printed circuit board 202. Similarly, the soldering device may be an induction soldering device or a wave soldering device. When an induction soldering device is used, it is necessary to apply solder (such as tin paste) to corresponding parts of the support plate 201, the main printed circuit board 202 and the coaxial cable 111 before soldering, and then use the heating coil of the induction soldering device to heat and melt the solder to perform soldering. When a wave soldering device is used, there is no need to apply solder to corresponding parts of the support plate 201, the main printed circuit board 202 and the coaxial cable 111, and the wave soldering device directly sprays liquid solder on corresponding soldering parts to perform soldering. In an embodiment of the present disclosure, it is also possible to apply solder to the accommodating portion 203 of the support plate 201 and solder the outer conductor 112 of the coaxial cable 111 to the accommodating portion 203 of the support plate 201 and on the soldering portion 206 of the main printed circuit board 202 at the same time.

When the support device 20 according to the second embodiment of the present disclosure is used, each coaxial cable 111 can be soldered on the support plate 201 and the main printed circuit board 202 at the same time through a single soldering operation. This not only significantly reduces the number of times of soldering and the time for soldering, but also ensures that all coaxial cables 111 have consistent soldering quality because only a single soldering operation is required. As a result, consistent electrical performance is ensured. In addition, the applicant has found that when the support plate 201 having the gap 205 and the main printed circuit board 202 having the soldering portion 206 are used, the soldering can be performed more quickly, and the soldered phase shifter has better electrical performance.

Exemplary embodiments according to the present disclosure have been described above with reference to the attached drawings. However, those skilled in the art should understand that various changes and modifications can be made to the exemplary embodiments of the present disclosure without departing from the gist and scope of the present disclosure. All changes and modifications are included in the protection scope of the present disclosure defined by the claims. The present disclosure is defined by the attached claims, and equivalents of these claims are also included.

1. A support device for a phase shifter for a base station antenna, including a support plate suitable for fixation of a main printed circuit board of the phase shifter, the support plate including a plate-shaped body and at least one support leg located at a lower portion of the body, at least one said support leg extending along a direction perpendicular to the body and being located on one side of the body, so that the support plate can be arranged in the base station antenna in a first orientation by at least one said support leg, or arranged in the base station antenna in a second orientation by the body itself according to layout requirements.

2. The support device for a phase shifter for a base station antenna according to claim 1, wherein the body includes a front surface and a rear surface, and at least one surface of the front surface and the rear surface is suitable for fixation of the main printed circuit board of the phase shifter.

3. The support device for a phase shifter for a base station antenna according to claim 2, wherein at least one said surface of the front surface and the rear surface includes one or more accommodating portions suitable for accommodation of outer conductors of one or more coaxial cables.

4. The support device for a phase shifter for a base station antenna according to claim 3, wherein the one or more accommodating portions are positioned to be near an end portion of a corresponding transmission line track of the main printed circuit board when the main printed circuit board of the phase shifter is positioned on at least one said surface, so that when the outer conductor of the coaxial cable is accommodated in the accommodating portion, an inner conductor of the coaxial cable can contact the end portion of the corresponding transmission line track to transmit a signal.

5. The support device for a phase shifter for a base station antenna according to claim 3, wherein at least one said surface of the front surface and the rear surface includes one or more support portions suitable for support of the main printed circuit board of the phase shifter.

6. The support device for a phase shifter for a base station antenna according to claim 5, wherein the support portion and the accommodating portion are spaced apart from each other by a gap penetrating the body of the support plate.

7. The support device for a phase shifter for a base station antenna according to claim 4, wherein at least one said surface includes one or more support protrusions for supporting the corresponding transmission line track of the main printed circuit board of the phase shifter, and the support protrusion has a contour that is the same as that of the corresponding transmission line track.

8. The support device for a phase shifter for a base station antenna according to claim 2, wherein at least one said surface includes a plurality of positioning protrusions for positioning the main printed circuit board of the phase shifter.

9. The support device for a phase shifter for a base station antenna according to claim 1, wherein a plurality of fixing lugs are provided at different positions of the body of the support plate for fixing the body of the support plate when the support plate is arranged in the second orientation by the body.

10. The support device for a phase shifter for a base station antenna according to claim 1, wherein a top portion of the support plate has a contour that is the same as that of a top portion of the main printed circuit board of the phase shifter.

11. The support device for a phase shifter for a base station antenna according to claim 1, wherein the body of the support plate includes a plurality of cavities penetrating the body.

12. The support device for a phase shifter for a base station antenna according to claim 1, wherein the support device further includes a sliding piece support member for a sliding piece of the phase shifter, one end of the sliding piece support member is rotatably fixed on the support plate, and the sliding piece support member can drive the sliding piece to rotate relative to the main printed circuit board when rotating, so as to adjust a phase of the phase shifter.

13. An assembly for a phase shifter for a base station antenna, wherein the assembly includes the support device for a phase shifter for a base station antenna according to claim 1 and at least one printed circuit board mounted on the support plate of the support device.

14. The assembly for a phase shifter for a base station antenna according to claim 13, wherein the assembly further includes one or more coaxial cables that are soldered on corresponding portions of the support plate and the printed circuit board.

15. A method for soldering a coaxial cable to a phase shifter for a base station antenna, including:
1) providing a support plate for the phase shifter, at least one surface of the support plate being suitable for fixation of a main printed circuit board of the phase shifter and including one or more accommodating portions suitable for accommodation of outer conductors of one or more coaxial cables;
2) placing the main primed circuit board of the phase shifter on the support plate so that an end portion of a corresponding transmission line track of the main printed circuit board is near the accommodating portion of the support plate;
3) placing the outer conductors of the one or more coaxial cables in the corresponding accommodating portions of the support plate respectively, and bringing inner conductors of the one or more coaxial cables into contact with the end portions of the corresponding transmission line tracks of the main printed circuit board; and
4) using a soldering device to solder the support plate, the main printed circuit board, and the coaxial cable, so as to solder the coaxial cable on the support plate and the main printed circuit board.

16. The method according to claim 15, wherein the soldering device is an induction soldering device, and wherein, the method comprises a step of applying solder to corresponding soldering parts of the support plate, the main printed circuit board and the coaxial cable before step 4).

17. The method according to claim 15, wherein the soldering device is a wave soldering device, and wherein, a liquid solder is applied directly to corresponding soldering parts of the support plate, the main printed circuit board and the coaxial cable in the step 4).

18. The method according to claim 15, wherein the support plate includes a support portion for supporting the main printed circuit board, the support portion is adjacent to the accommodating portion, and at least a part of a back surface of the main printed circuit board is soldered on the support portion.

19. The method according to claim 15, wherein the support plate includes a support portion for supporting the main printed circuit board, the support portion and the accommodating portion are spaced apart from each other by a gap penetrating the body of the support plate, the main printed circuit board includes a soldering portion suitable for soldering of the outer conductor of the coaxial cable, and in step 2), the soldering portion is arranged above the gap without contacting the support plate.

20. The method according to claim 19, wherein the soldering portion of the main printed circuit board includes an opening, and in step 3), the outer conductor of the coaxial cable is placed in the opening.
